(19) United States
(12) Patent Application Publication
(10) Pub. No.: US 2006/0125012 A1
(43) Pub. Date: Jun. 15, 2006

(54) Varactor

(75) Inventor: Mohammed A. Fathimulla, Ellicott City, MD (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc.

(21) Appl. No.: 11/008,473

(22) Filed: Dec. 9, 2004

(51) Int. Cl. H01L 29/74

(52) U.S. Cl. 257/351; 257/348; 257/595

(57) ABSTRACT

A varactor having a capacitance includes a depletion mode transistor having a gate, a source, and a drain and an enhancement mode transistor also having a gate, a source, and a drain. The gates of the depletion mode transistor and the enhancement mode transistor are coupled together, the sources of the depletion mode transistor and the enhancement mode transistor are coupled together, and the drains of the depletion mode transistor and the enhancement mode transistor are coupled together. The enhancement mode transistor has a p/n junction. A bias source is coupled to the gates and the sources and drains so as to control the capacitance.

### TECHNICAL FIELD OF THE INVENTION

The present invention relates to a varactor such as an integrated varactor.

### BACKGROUND OF THE INVENTION

The present invention relates to a varactor such as an integrated varactor.

### BACKGROUND OF THE INVENTION

A varactor is an electrical device, usually a reversed biased diode, whose capacitance is controlled by a suitable voltage or current bias. Varactors are used in a wide variety of applications such as tuners, phase locked loop circuits, and voltage controlled oscillators. In such applications, the output frequency of a circuit or circuit element is controlled according to an applied voltage or current bias.

Known varactors such as PIN and Schottky barrier diodes and MOS capacitors have a number of disadvantages. One such disadvantage for the MOS capacitor is that the range of capacitance variation of known varactors is quite limited. For example, the capacitance of an MOS varactor usually varies approximately by a factor of two over a voltage range of approximately one volt for MOS and 12 volts for PIN. In many applications such as low voltage wireless communications, a capacitance variation by a larger factor over the same voltage range is often desirable. Further, known MOS based varactors can achieve only limited tuning ranges, can be used with only small voltage swings, are not easily programmable, and are difficult to accurately control. The varactors based on PIN diodes require a large voltage such that they are not suitable for low power applications. In addition, a dual voltage CMOS process is required to integrate PIN diodes.

The present invention is directed to a varactor that overcomes or alleviates one or more of these or other problems.

### SUMMARY OF THE INVENTION

In accordance with one aspect of the present invention, a varactor having a capacitance comprises a depletion mode transistor, an enhancement mode transistor, and a bias source. The depletion mode transistor has a gate, a source, and a drain. The enhancement mode transistor has a gate, a source, and a drain. The gates of the depletion mode transistor and the enhancement mode transistor are coupled together, the sources and drains of the depletion mode transistor and the enhancement mode transistor are coupled together, and the enhancement mode transistor has a p/n junction. The a bias source is coupled to the gates and the sources and drains so as to control the capacitance.

In a dependent feature of this aspect of the present invention, the enhancement mode transistor has a p/n junction in the form of body ties.

In accordance with another aspect of the present invention, a method of determining temperature comprises the following: detecting a leakage current through a p/n diode formed by a body region and a source region of a transistor, wherein the transistor includes a gate and a drain region, and wherein the body region separates the source and drain regions; and, converting the leakage current to temperature.

In accordance with yet another aspect of the present invention, a varactor having a capacitance comprises a gate, a source, a drain, and a body tie. The body tie forms a p/n junction with the source, and the p/n junction comprises the capacitance of the varactor.

In accordance with still another aspect of the present invention, a device comprises a depletion mode transistor and an enhancement mode transistor and can be used as a power device having large voltage swing from negative to positive gate bias.

In accordance with a further aspect of the present invention, a varactor comprises a depletion mode transistor and an enhancement mode transistor.

In accordance with a still further aspect of the present invention, a power transistor comprises a depletion mode transistor, and an enhancement mode transistor. The depletion mode transistor has a gate, a source, and a drain. The enhancement mode transistor has a gate, a source, and a drain. The gates of the depletion mode transistor and the enhancement mode transistor are coupled together, the sources of the depletion mode transistor and the enhancement mode transistor are coupled together, and the drains of the depletion mode transistor and the enhancement mode transistor are coupled together.

### BRIEF DESCRIPTION OF THE DRAWING

These and other features and advantages will become more apparent from a detailed consideration of the invention when taken in conjunction with the drawings in which:

FIG. 1 illustrates a depletion mode transistor that can be used in fabricating a varactor according to the present invention;

FIG. 2 illustrates an enhancement mode transistor that can be used in fabricating a varactor according to the present invention;

FIG. 3 illustrates a first embodiment of a varactor according to the present invention that includes both a depletion mode transistor and an enhancement mode transistor;

FIG. 4 illustrates a second embodiment of a varactor according to the present invention that includes both the multiple fingers (gate) depletion mode transistor and the enhancement mode transistor;

FIG. 5 illustrates a varactor according to the present invention that is provided with a transverse body tie; and,

FIG. 6 illustrates a varactor according to the present invention that is provided with a parallel body tie.

### DETAILED DESCRIPTION

As shown in FIG. 1, a depletion mode transistor 10 includes a silicon substrate 12, a buried oxide layer 14 over the silicon substrate 12, and a silicon layer 16 over the buried oxide layer 14. The silicon layer 16, for example, may have an n body region 17 and is suitably doped to form an n+ source region 18 and an n+ drain region 20. The depletion mode transistor 10 includes a gate 22 having a gate oxide layer 24 and a gate polysilicon 26. The gate oxide layer 24 is formed over the silicon layer 16, and the gate polysilicon 26 is formed over the gate oxide layer 24.

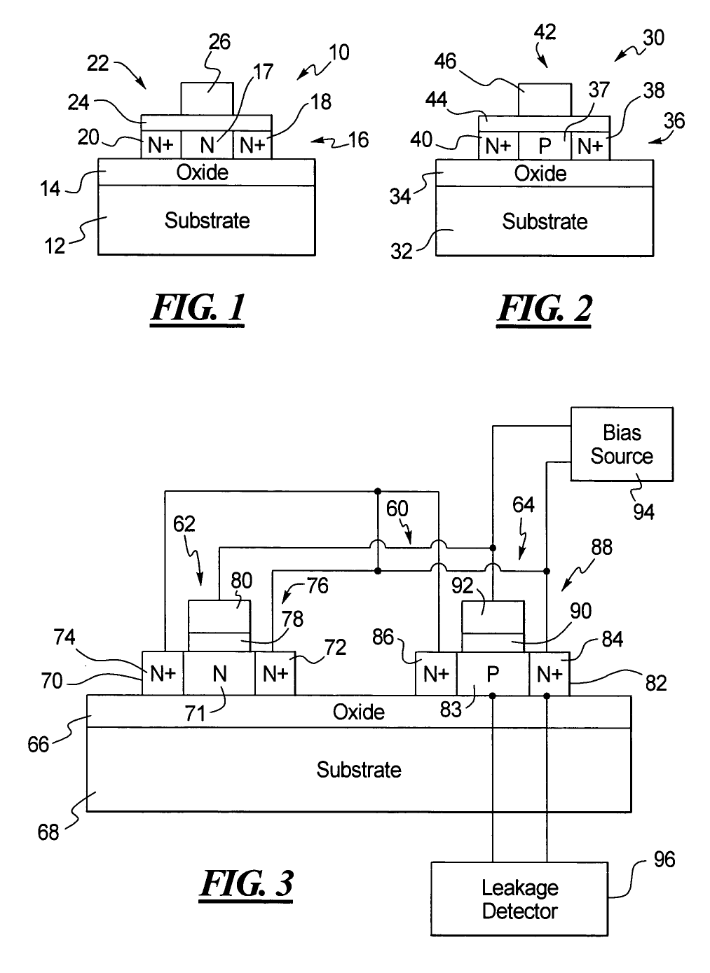

As shown in FIG. 2, an enhancement mode transistor 30 includes a silicon substrate 32, a buried oxide layer 34 over the silicon substrate 32, and a silicon layer 36 over the buried oxide layer 34. The silicon layer 36, for example, may have a p body region 37 and is suitably doped to form an n+ source region 38 and an n+ drain region 40. A gate 42 of the enhancement mode transistor 30 includes a gate oxide layer 44 and a gate polysilicon 46. The gate oxide layer 44 is formed over the silicon layer 36, and the gate polysilicon 46 is formed over the gate oxide layer 44.

According to a first embodiment of the present invention, a depletion mode transistor of the sort shown in FIG. 1 and an enhancement mode transistor of the sort shown in FIG. 2 can be combined to form a varactor 60 shown in FIG. 3. Thus, the varactor 60 includes a depletion mode transistor 62 and an enhancement mode transistor 64 formed over a common buried oxide layer 66 that is formed over a common silicon substrate 68.

The depletion mode transistor 62 includes a silicon layer 70 over the common buried oxide layer 66. The silicon layer 70, for example, may have an n body region 71 and is suitably doped to form an n+ source region 72 and an n+ drain region 74. The depletion mode transistor 62 also includes a gate 76 having a gate oxide layer 78 and a gate polysilicon 80. The gate oxide layer 78 is formed over the silicon layer 70, and the gate polysilicon 80 is formed over the gate oxide layer-78.

The enhancement mode transistor 64 includes a silicon layer 82 formed over the common buried oxide layer 66. The silicon layer 82, for example, may have a p body region 83 and is suitably doped to form an n+ source region 84 and an n+ drain region 86. A gate 88 of the enhancement mode transistor 64 includes a gate oxide layer 90 and a gate polysilicon 92. The gate oxide layer 90 is formed over the silicon layer 82, and the gate polysilicon 92 is formed over the gate oxide layer 90.

As shown in FIG. 3, the gates 76 and 88 are coupled together, the n+ source region 72 of the depletion mode transistor 62 is coupled to the n+ source region 84 of the enhancement mode transistor 64, and the n+ drain region 74 of the depletion mode transistor 62 is coupled to the n+ drain region 86 of the enhancement mode transistor 64. To implement the combination of the enhancement mode transistor 64 and the depletion mode transistor 62 as the varactor 60, the source regions 72 and 84 and the drain regions 74 and 86 are also connected together.

A bias source 94 is coupled between the combined source regions 72 and 84 and the drain regions 74 and 86 on the one hand and the combined gates 76 and 88 on the other in order to control the capacitance of the varactor 60.

The varactor 60 achieves a Cₘₐₓ/Cₘᵢₙ variation that is greater than 2:1 compared to the Cₘₐₓ/Cₘᵢₙ variation of known varactors for the same biasing change, and the capacitance range of the varactor 60 is easier to control than the capacitance ranges of known varactors.

Also, the body region 83 may be suitable doped near the source region 84 of the enhancement mode transistor 64 to provided a p+ body tie region (not shown in the FIG. 3). A bias source may be applied to the p/n junction formed by the n+ source region 84 and this p+ body tie region (not shown in FIG. 3) in order to fine control the capacitance of the varactor 60.

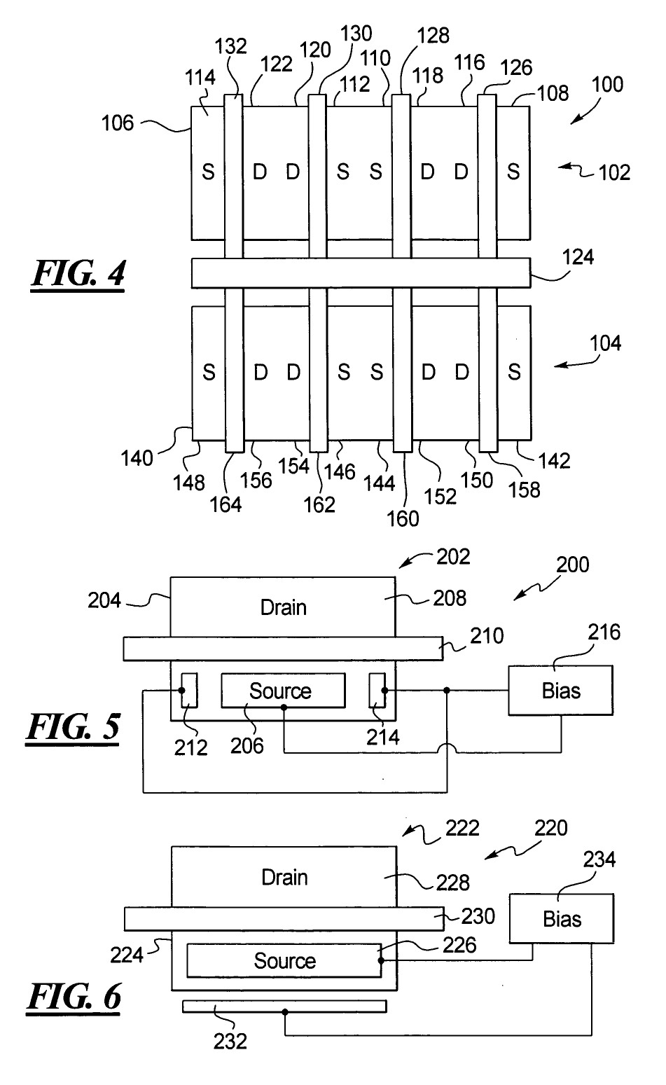

According to a second embodiment of the present invention, a depletion mode transistor and an enhancement mode transistor having multiple gates can be combined to form a varactor 100 shown in FIG. 4. The varactor 100 includes a multiple finger depletion mode transistor 102 and a multiple finger enhancement mode transistor 104 which may be formed over a common silicon substrate and a common buried oxide layer as in the case of the varactor 60.

The multiple finger depletion mode transistor 102 includes a silicon layer 106. The silicon layer 106 is suitably doped to form a plurality of n+ source regions 108, 110, 112, and 114 and a plurality of n+ drain regions 116, 118, 120, and 122. Each source region of the depletion mode transistor 102 is separated from its adjacent drain regions by an n body region. A polysilicon gate 124 of the varactor 100 has a plurality of gate fingers 126, 128, 130, and 132 forming a gate comb structure for the depletion mode transistor 102.

An n body region of the multiple finger depletion mode transistor 102 underlies the gate finger 126 and separates the source region 108 from the drain region 116. Similarly, an n body region of the multiple finger depletion mode transistor 102 underlies the gate finger 128 and separates the source region 110 from the drain region 118, an n body region of the multiple finger depletion mode transistor 102 underlies the gate finger 130 and separates the source region 112 from the drain region 120, and an n body region of the multiple finger depletion mode transistor 102 underlies the gate finger 132 and separates the source region 114 from the drain region 122. Accordingly, the multiple finger depletion mode transistor 102 is essentially comprised of a plurality of depletion mode transistors.

The multiple finger enhancement mode transistor 104 includes a silicon layer 140. The silicon layer 140 is suitably doped to form a plurality of n+ source regions 142, 144, 146, and 148 and a plurality of n+ drain regions 150, 152, 154, and 156. Each source region of the multiple finger enhancement mode transistor 104 is separated from its adjacent drain regions by a p body region. The polysilicon gate 124 of the varactor 100 has a plurality of gate fingers 158, 160, 162, and 164 forming a gate comb structure for the multiple finger enhancement mode transistor 104. A p body region of the multiple finger enhancement mode transistor 104 underlies the gate finger 158 and separates the source region 142 from the drain region 150. Similarly, a p body region of the multiple finger enhancement mode transistor 104 underlies the gate finger 160 and separates the source region 144 from the drain region 152, a p body region of the multiple finger enhancement mode transistor 104 underlies the gate finger 162 and separates the source region 146 from the drain region 154, and a p body region of the enhancement mode transistor 104 underlies the gate finger 164 and separates the source region 140 from the drain region 156. Accordingly, the multiple finger enhancement mode transistor 104 is comprised of a plurality of enhancement mode transistors.

As desired, the source regions 108, 110, 112, and 114 may be coupled together, and the drain regions 126, 128, 130, and 132 may likewise be coupled together. Similarly, the source regions 142, 144, 146, and 148 may be coupled together, and the drain regions 150, 152, 154, and 156 may likewise be coupled together. Moreover, the source regions 108, 110, 112, and 114, the source regions 142, 144, 146, and 148, the drain regions 126, 128, 130, and 132, and the drain regions 150, 152, 154, and 156 may all be coupled together.

A bias can be applied between the gate 124 and the source and drain regions commonly coupled together so as to control the capacitance of the varactor 100. The number of gate fingers depends on the required capacitance. The varactor 100 achieves a Cₘₐₓ/Cₘᵢₙ variation that is greater than 2:1 compared to the Cₘₐₓ/Cₘᵢₙ variation of known varactors for the same biasing change, and the capacitance range of the varactor 100 is easier to control than the capacitance ranges of known varactors.

A body ties may be employed in combination with the varactor 100 ion a manner similar to that discussed above in connection with FIG. 3.

A varactor 200 employing a body tie is shown in FIG. 5 and includes, for example, an enhancement mode transistor 202 which may be formed over a silicon substrate and a buried oxide layer as in the case of the varactor 60. The enhancement mode transistor 202 includes a silicon layer 204 in which are formed an n+ source region 206 and an n+ drain region 208 separated by a p body region underlying a polysilicon gate 210. The silicon layer 204 may be doped to form one or more p+ type body ties 212 and/or 214. Multiple body ties are used for enhancement mode transistor, and the separation distance between the body ties such as 212 and 214 are governed by the design rules. However for the present application, only body ties at the edge are used in order to make the fabrication simple. The p+ type body tie 212 forms a p/n junction with the n+ source region 206. The capacitance of the varactor 200 can be used, for example, to fine tune an oscillator used on wireless communications or in other applications.

A bias source 216 is connected between the body ties 212 and/or 214 and the source 206.

Instead of forming the body tie at the end of an elongated source region as shown in FIG. 5, the body tie may be formed along (parallel to) an elongated source region as shown in FIG. 6. As shown in FIG. 6, a body tie varactor 220 includes, for example, an enhancement mode transistor 222 which may be formed over a silicon substrate and a buried oxide layer as in the case of the varactor 60. The enhancement mode transistor 222 includes a silicon layer 224 in which are formed an n+ source region 226 and an n+ drain region 228 separated by a p body region underlying a polysilicon gate 230. The silicon layer 224 may be doped to form a p+ type body tie 232. The p+ type body tie 232 forms a p/n junction with the n+ source region 226. The capacitance of the varactor 220 also can be used, for example, to fine tune an oscillator used on wireless communications or in other applications.

A bias source 234 is connected between the body tie 232 and the source 226.

Certain modifications of the present invention have been discussed above. Other modifications will occur those skilled in the art of the present invention. For example, monitoring the junction temperature of multi-finger high power and high temperature devices such as CMOS, LDMOS, and DMOS is essential to avoid destructive burnout. Therefore, a leakage detector 96 can be used to detect leakage current through any one or more of the p/n diodes of the varactors 60, 100, 200, and 220 as an indication of the temperature of the associated device top minimize failure. The p/n diode has an exponential temperature versus leakage current relationship. Accordingly, once the leakage current is known, temperature can easily be determined based on this relationship. For this purpose, the bias sources for the varactors 60, 100, 200, and 220 94 may include a leakage detector in order to detect this leakage current. Alternatively, the bias sources can be replaced by a leakage current detector when temperature is to be determined. The p/n diode can be pulsed periodically, such as once per hour, in the reverse direction at the time that leakage current is to be detected.

Moreover, the depletion mode transistors and enhancement mode transistors forming the varactors described above are nMOS devices. Instead, the depletion mode transistors and enhancement mode transistors forming the varactors described above may be pMOS devices. If pMOS transistors are used for the varactors 200 (202) and 220, the body ties may be provided as n doped regions of the appropriate region of the substrate.

In accordance with still another modification of the present invention, a device comprises a depletion mode transistor and an enhancement mode transistor and can be used as a power device having large voltage swing from negative to positive gate bias. FIG. 4 shows a typical layout of the power device and requires connecting all the gates, sources, and drains separately. To operate as a power device the bias is applied between gate-source and drain-source. The number of fingers is selected depending on the design rules and the required current density. The gate length depends on the frequency of operation. The depletion transistor is designed to avoid deep depletion by selecting appropriate doping of the active channel. An example is to implant p-type dopant at the back of the n-layer.

In addition, the temperature sensor described above can be implemented for the power device. Furthermore, a power device based on the varactor 100 is based on the n-type depletion mode transistors 102 and the n-type enhancement mode transistors 104. Instead, the power device may be based on p-enhancement mode and p-depletion mode transistors.

In accordance with still another modification of the present invention, a depletion mode transistor can be used in applications where no body tie devices are required to be compatible to GaAs based circuits. The example is as a shunt device for the design of the RF switch.

Further, these inventions can be implemented in bulk Si, SOI, InP, SiGe, and GaN based technologies.

Accordingly, the description of the present invention is to be construed as illustrative only and is for the purpose of teaching those skilled in the art the best mode of carrying out the invention. The details may be varied substantially without departing from the spirit of the invention, and the exclusive use of all modification which are within the scope of the appended claims is reserved.

1. A varactor having a capacitance comprising:
a depletion mode transistor having a gate, a source, and a drain;
an enhancement mode transistor having a gate, a source, and a drain, wherein the gates of the depletion mode transistor and the enhancement mode transistor are coupled together, wherein the sources and drains of the depletion mode transistor and the enhancement mode transistor are coupled together, and wherein the enhancement mode transistor has a p/n junction; and,
a bias source coupled to the gates and the sources and drains so as to control the capacitance.

2. The varactor of claim 1 wherein the depletion mode transistor and the enhancement mode transistor share a common silicon substrate and a common buried oxide layer.

3. The varactor of claim 1 wherein the gate comprises a polysilicon gate.

4. The varactor of claim 3 wherein the depletion mode transistor and the enhancement mode transistor share a common silicon substrate and a common buried oxide layer.

5. The varactor of claim 1 wherein the source of the depletion mode transistor comprises a plurality of source regions, wherein the drain of the depletion mode transistor comprises a plurality of drain regions, wherein the gate of the depletion mode transistor comprises a plurality of gate fingers, wherein the source of the enhancement mode transistor comprises a plurality of source regions, wherein the drain of the enhancement mode transistor comprises a plurality of drain regions, and wherein the gate of the enhancement mode transistor comprises a plurality of gate fingers.

6. The varactor of claim 5 wherein the gate fingers of the depletion mode transistor and of the enhancement mode transistor are coupled together.

7. The varactor of claim 5 wherein the depletion mode transistor and the enhancement mode transistor share a common silicon substrate and a common buried oxide layer.

8. The varactor of claim 5 wherein the gate fingers comprise corresponding polysilicon gate fingers.

9. The varactor of claim 1 further comprising a leakage current detector coupled to the p/n junction enabling temperature to be determined as a function of leakage current though the p/n junction.

10. The varactor of claim 1 further comprising a body tie forming a capacitor with the source of the enhancement mode transistor, wherein the body tie has a conductivity type opposite to the conductivity type of the source with which the body tie forms the capacitor.

11. The varactor of claim 10 wherein the source of the enhancement mode transistor comprises an elongated side, and wherein the body tie is transverse to the elongated side.

12. The varactor of claim 10 wherein the source of the enhancement mode transistor comprises an elongated side, and wherein the body tie is parallel to the elongated side.

13. A method of determining temperature comprising:
detecting a leakage current through a p/n diode formed by a body region and a source region of a transistor, wherein the transistor includes a gate and a drain region, and wherein the body region separates the source and drain regions; and,
converting the leakage current to temperature.

14. The method of claim 13 wherein the transistor comprises an enhancement mode transistor.

15. The method of claim 13 wherein the transistor comprises a gate oxide between the gate and the body region.

16. The method of claim 13 wherein the gate comprise a polysilicon gate.

17. A varactor having a capacitance comprising:
a gate;
a source;
a drain; and,
a body tie forming a p/n junction with the source, wherein the p/n junction comprises the capacitance of the varactor.

18. The varactor of claim 17 wherein the gate, the source, and the drain form an enhancement mode transistor.

19. The varactor of claim 17 wherein the gate, the source, and the drain form a depletion mode transistor and an enhancement mode transistor.

20. The varactor of claim 19 wherein the depletion mode transistor and the enhancement mode transistor share a common silicon substrate and a common buried oxide layer.

21. The varactor of claim 17 wherein the gate comprises a polysilicon gate.

22. The varactor of claim 17 wherein the source comprises a plurality of source regions, wherein the drain comprises a plurality of drain regions, wherein the gate comprises a plurality of gate fingers, and wherein the body tie forms the p/n junction with at least one of the source regions.

23. The varactor of claim 17 wherein the source comprises an elongated side, and wherein the body tie is transverse to the elongated side.

24. The varactor of claim 17 wherein the source comprises an elongated side, and wherein the body tie is parallel to the elongated side.

25. A varactor comprising:
a depletion mode transistor;
an enhancement mode transistor; and,
a bias source coupled to both the depletion mode transistor and the enhancement mode transistor and arranged to control the depletion mode transistor and the enhancement mode transistor so as to control a capacitance of the varactor.

26. The varactor of claim 25 wherein the depletion mode transistor and the enhancement mode transistor share a common silicon substrate and a common buried oxide layer.

27. The varactor of claim 25 wherein the depletion mode transistor comprises a gate, wherein the enhancement mode transistor comprises a gate, and wherein each of the gates comprises a polysilicon gate.

28. The varactor of claim 25 wherein the depletion mode transistor comprises a plurality of source regions, a plurality of drain regions, and a plurality of gate fingers, wherein the enhancement mode transistor comprises a plurality of source regions, a plurality of drain regions, and a plurality of gate fingers.

29. The varactor of claim 28 wherein the gate fingers of the depletion mode transistor and of the enhancement mode transistor are coupled together.

30. The varactor of claim 25 further comprising a leakage current detector coupled to a p/n junction of the enhancement mode transistor enabling temperature to be determined as a function of leakage current though the p/n junction.

31. The varactor of claim 25 wherein the depletion mode transistor and the enhancement mode transistor share a common gate.

32. A power transistor comprising:
a depletion mode transistor having a gate, a source, and a drain; and,
an enhancement mode transistor having a gate, a source, and a drain, wherein the gates of the depletion mode transistor and the enhancement mode transistor are coupled together, wherein the sources of the depletion mode transistor and the enhancement mode transistor are coupled together, and wherein the drains of the depletion mode transistor and the enhancement mode transistor are coupled together.

33. The transistor of claim 32 wherein the depletion mode transistor and the enhancement mode transistor share a common silicon substrate and a common buried oxide layer.

34. The transistor of claim 32 wherein the gate comprises a polysilicon gate.

35. The transistor of claim 34 wherein the depletion mode transistor and the enhancement mode transistor share a common silicon substrate and a common buried oxide layer.

36. The transistor of claim 32 wherein the source of the depletion mode transistor comprises a plurality of source regions coupled together, wherein the drain of the depletion mode transistor comprises a plurality of drain regions coupled together, wherein the gate of the depletion mode transistor comprises a plurality of gate fingers coupled together, wherein the source of the enhancement mode transistor comprises a plurality of source regions coupled together, wherein the drain of the enhancement mode transistor comprises a plurality of drain regions coupled together, and wherein the gate of the enhancement mode transistor comprises a plurality of gate fingers coupled together.

37. The transistor of claim 36 wherein the depletion mode transistor and the enhancement mode transistor share a common silicon substrate and a common buried oxide layer.

38. The transistor of claim 36 wherein the gate fingers comprise corresponding polysilicon gate fingers.

39. The transistor of claim 32 further comprising a leakage current detector coupled to a p/n junction enabling temperature to be determined as a function of leakage current though the p/n junction.
